(19) United States
(12) Patent Application Publication
(10) Pub. No.: US 2023/0296693 A1
(43) Pub. Date: Sep. 21, 2023

(54) DIAGNOSTIC METHOD OF CROSS-WIRE FAULT

(71) Applicant: Intellihot, Inc., Galesburg, IL (US)

(72) Inventors: Sridhar Deivasigamani, Peoria, IL (US); Sivaprasad Akasam, Dunlap, IL (US)

(21) Appl. No.: 17/699,125

(22) Filed: Mar. 20, 2022

(51) Int. Cl. G01R 31/55; F24H 15/104

(52) U.S. Cl. CPC G01R 31/55; F24H 15/104

(57) ABSTRACT

A diagnostic method of a system having at least one device under test and at least one peripheral device, the diagnostic method including obtaining a response of a test action conducted on the at least one device under test; and obtaining a response of a test action conducted on the at least one peripheral device; wherein if both the response of the test action conducted on the at least one device under test deviates from an expected result based on the test action conducted on the at least one device under test and the response of the test action conducted on the at least one peripheral device deviates from an expected result based on the test action conducted on the at least one peripheral device, a cross-wire fault is raised.

### BACKGROUND OF THE INVENTION

### 1. The Field of the Invention

The present invention relates generally to a diagnostic method for detecting a cross-wire fault. More specifically, the present invention is directed to a diagnostic method for detecting a cross-wire fault and identifying one or more device and/or one or more component responsible for the cross-wire fault.

### 2. Background Art

Traditional failure mode detection means are targeted on the performance of specific devices and/or components in question for a more accurate detection of failure modes or identification of devices and/or components responsible for the failure/s. For instance, in order to identify a failure mode associated with the process of water heating of a water heater or the equipment associated with heating in a water heater, various components of the water heater are monitored as the failure of any one of the components may contribute to the failure in water heating. Typical components found in a water or fluid heating system include one or more blowers, igniters, burners, pumps, heat exchangers and various flow valves, etc. The failure of one of these components can be sufficient to cause a water heater to fail and requires an effective diagnostic method to properly identify the failed component and its root cause of failure. However, even an effective but heater-centric diagnostic method is not useful for detecting a cross-wire fault. A mis-wiring or cross-wire event can cause highly unusual behaviors to be exhibited in a monitored device or component. Lacking an effective diagnostic tool or method for detecting a cross-wire fault, the realization of the existence of a cross-wire fault typically falls on the shoulders of alert, highly-skilled and experienced service personnel who are capable in noticing unusual behaviors exhibited in one or more devices that are outside of the device or component being monitored.

There exists a need for a diagnostic method capable of detecting a cross-wire fault and identifying devices or components responsible for the cross-wire fault such that a service action can be taken quickly and a service action that is focused on the appropriate devices or components in question.

### SUMMARY OF THE INVENTION

In accordance with the present invention, there is provided a diagnostic method of a system having at least one device under test and at least one peripheral device, the diagnostic method including:
(a) obtaining a response of a test action conducted on the at least one device under test; and
(b) obtaining a response of a test action conducted on the at least one peripheral device,
wherein if the response of the test action conducted on the at least one device under test deviates from an expected result based on the test action conducted on the at least one device under test and the response of the test action conducted on the at least one peripheral device deviates from an expected result based on the test action conducted on the at least one peripheral device, a cross-wire fault is raised and if the response of the test action conducted on the at least one device under test deviates from an expected result based on the test action conducted on the at least one device under test and the response of the test action conducted on the at least one peripheral device does not deviate from an expected result based on the test action, a device under test fault is raised.

In one embodiment, the at least one device under test is a valve and the test action conducted on the at least one device under test includes opening the valve for allowing a flow of water and the response of the test action conducted on the at least one device under test includes a temperature response of the flow of water due to the act of opening the valve. In one embodiment, the at least one device under test is a heating device and the test action conducted on the at least one device under test comprises turning on the at least one device under test. In one embodiment, the diagnostic method includes running the test action as part of a normal operation of the at least one device under test. In one embodiment, the diagnostic method further includes running the test action as part of an exerciser.

An object of the present invention is to provide a diagnostic method configured for not only detecting problems with parts or components specific to a specific module under diagnosis but also faults that occur due to components not specific to the specific module under diagnosis or “cross-wire” faults.

Whereas there may be many embodiments of the present invention, each embodiment may meet one or more of the foregoing recited objects in any combination. It is not intended that each embodiment will necessarily meet each objective. Thus, having broadly outlined the more important features of the present invention in order that the detailed description thereof may be better understood, and that the present contribution to the art may be better appreciated, there are, of course, additional features of the present invention that will be described herein and will form a part of the subject matter of this specification.

### BRIEF DESCRIPTION OF THE DRAWINGS

In order that the manner in which the above-recited and other advantages and objects of the invention are obtained, a more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 is a diagram depicting a diagnostic method for detecting cross-wire faults.

FIG. 2 is a diagram depicting a heating system where the heating output is jointly or alternatively provided by any one or more heaters of the heating system.

FIG. 3 is a diagram depicting the heating system of FIG. 2 with the exception that the heater controllers of heaters A and B have been mis-wired.

### PARTS LIST

2—desired test action
4—decision on whether test action is normal operation
6—act of selecting test action as part of normal operation
8—act of selecting test action as exerciser
10—act of running test action
12—wait time
14—check to determine whether wait time has expired
16—act of getting response of test action from tested device
18—act of getting response of test action from peripheral device
20—tested device or device under test
22—peripheral device
24—component of tested device
26—component of tested device
28—component of peripheral device
30—component of peripheral device
32—act of determining whether response deviates from expected result
34—act of determining whether response deviates from expected result
36—test action database
38—result indicating tested device fault
40—result indicating peripheral cross-wire fault
42—heating system
44—heater
46—heater controller
48—incorrectly connected wire
50—igniter
52—temperature sensor
54—burner
56—valve/flow sensor/inlet temperature sensor package
58—heat exchanger
60—incorrectly connected wire PARTICULAR ADVANTAGES OF THE INVENTION

The present diagnostic methods is capable of detecting cross-wire faults or identifying anomalies that occur in peripheral devices and associating such event/s to the device under test as cross-wire faults. Compared to conventional diagnostic methods, the present method does not rely on chance discoveries of faults in identifying cross-wire faults.

### DETAILED DESCRIPTION OF A PREFERRED EMBODIMENT

The term “about” is used herein to mean approximately, roughly, around, or in the region of. When the term “about” is used in conjunction with a numerical range, it modifies that range by extending the boundaries above and below the numerical values set forth. In general, the term “about” is used herein to modify a numerical value above and below the stated value by a variance of 20 percent up or down (higher or lower).

A tested device or device under test, as used herein, refers to a device having properties, e.g., output water temperature, water pressure, rate of output water temperature change, etc., that are monitored for performance, potential problems or failures. A device under test can be tested after it has responded to a control input exerted by a controller configured to control the tested device.

A peripheral device, as used herein, refers to a device that is part of a larger system encompassing a tested device or a device under test but is not configured as a matter of normal operation to receive a control input from a controller configured to control a tested device.

An exerciser, as used herein, refers to a diagnostic routine executed or run outside of a normal operation of a tested device. The diagnostic routine may involve deliberately turning on or off one or more components at various times and in various sequences to produce responses or property changes of the tested device such that they may be obtained and evaluated in order to determine whether the responses meet expected results. This diagnostic routine is necessary if the normal operation of a tested device is incapable of producing an unexpected result, especially in a reasonable period of time or usage within which an anomaly in the device response or property is sought.

A “cross-wire” fault, as used herein, is a fault that is not directly related to the device/s, component/s or part/s under test. A “cross-wire” fault occurs due to at least one incorrect connection of a control or power wire to a component of a peripheral device. Although it is also possible for an incorrect connection to be made of a control or power wire to a component of the same device, it is unlikely to occur due to the specializations in connectors, wires or cables for different types of components in a device. For example, in a heating system having more than one heater, a mis-wiring event of a flow valve of a first heater can cause a flow in the second heater as the flow valve of the second heater is opened instead. Without a cross-wire-enabled diagnostic method, this heating system-level fault would not be detected or it would only be detected by an alert service personnel that happened to notice discrepancies in the manner in which the first heater and second heater operated.

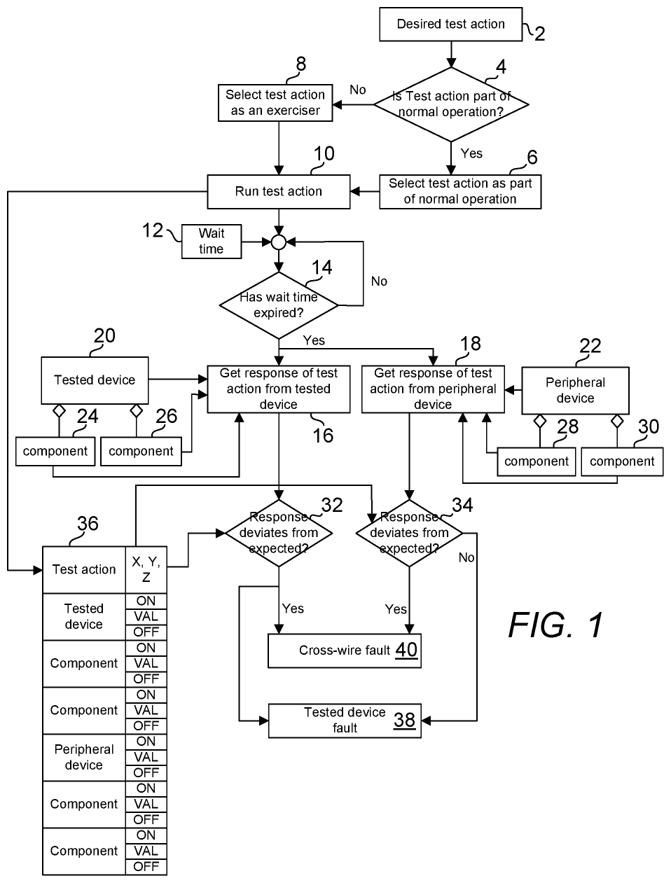

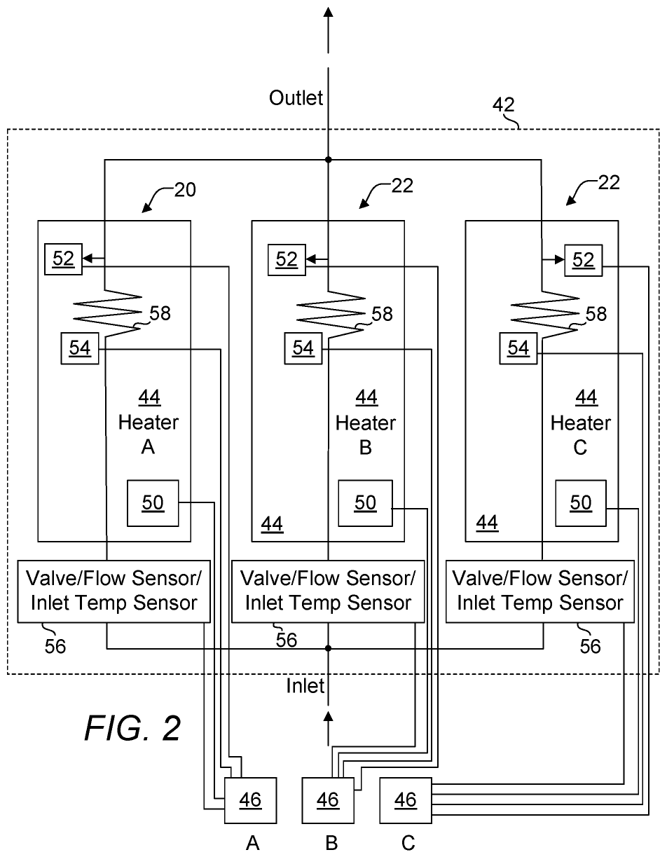

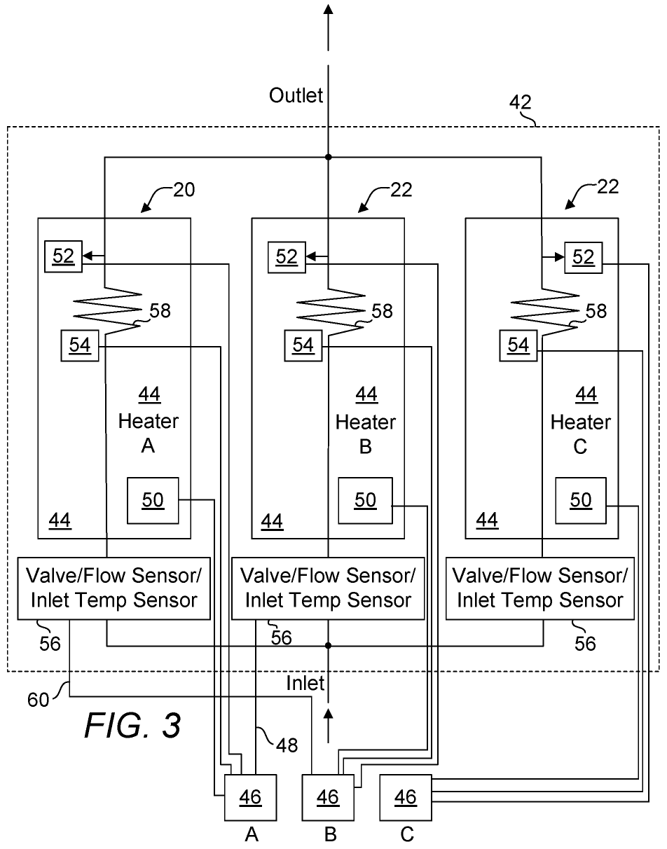

FIG. 1 is a diagram depicting a diagnostic method for detecting cross-wire faults. This diagnostic method is applicable to a system having at least one device under test 20 and at least one peripheral device 22. In general, the diagnostic method includes obtaining a response of a test action 2 conducted on the at least one device under test and obtaining a response of a test action conducted on the at least one peripheral device. If both the response of the test action 2 conducted on the at least one device under test 20 deviates from an expected result based on the test action conducted on the at least one device under test and if the response of the test action conducted on the at least one peripheral device deviates from an expected result based on the test action conducted on the at least one peripheral device, a cross-wire fault is said to have occurred and a cross-wire fault is raised. If the response of the test action conducted on the at least one device under test deviates from an expected result based on the test action conducted on the at least one device under test but the response of the test action conducted on the at least one peripheral device does not deviate from an expected result based on the test action conducted on the at least one peripheral device, a tested device fault is said to have occurred and a tested device fault is raised. In one embodiment, the diagnostic method includes running 6 the test action as part of a normal operation of the at least one device under test. In another embodiment, the diagnostic method further includes running 8 the test action as part of an exerciser. The decision 4 for running a test action as a part of a normal operation or an exerciser can be made at an interface presenting either a normal operation option or an exerciser option to a user or service personnel. If the test action is selected as a normal operation test action, the normal operation of the device under test can proceed normally while the diagnosis routine is activated. If the test action must be run as a part of an exerciser, a normal operation must be prevented from starting once the exerciser is under way. Upon selecting a test action, it can then be run as shown in part 10. When a test action is run as a part of a normal operation, no deliberate efforts have been invested in “creating” or “recreating” a fault and the fault can be obtained simply by running the tested device to deliver a service or product, e.g., heated water, etc., it is designed to do. For some tests, a delay must be allowed before a response can be obtained and analyzed. Here, a wait time 12 is allowed to expire upon starting the test action. Therefore, a check 14 for the expiration of the wait time is required to determine whether it is time to get a response of the test action just run of the tested device and the peripheral device. It shall be noted that, upon expiration of the timer, responses of test actions of the tested device 20 as well as the peripheral device 22 are obtained as shown in steps 16 and 18. In a multi-device system such as one shown in FIG. 1, there can be more than one device. Here, there is only one peripheral device 22 shown although there can be more than one peripheral device 22. The tested device 20 is shown to have two components 24, 26 although, again, there can be one or more than one component in a tested device 20. The peripheral device 22 is shown to have two components 28, 30 although, yet again, there can be one or more than one component in a peripheral device 22. The responses of the test action exerted on the tested device are then compared to the responses obtained from a test action database 36 in step 32. In one embodiment, the database 36 includes information regarding a plurality of test actions, the specific tested devices corresponding to the plurality of test actions and their states and conditions, the specific peripheral devices corresponding to the plurality of test actions and their states and conditions, etc. The response of the test action for the peripheral device is then compared to the responses obtained from a test action database 36 in step 34. If the responses or results of the tested device deviates from the expected response based on the test action exerted on the tested device while the response of the peripheral device does not deviate from the expected response based on the test action exerted on the tested device, a tested device fault 38 is said to have occurred. If the response or result of the tested device deviates from the expected response based on the test action exerted on the tested device while the response of the peripheral device also deviates from the expected response based on the test action exerted on the peripheral device, a cross-wire fault 40 is said to have occurred. It shall be noted that, in the latter combination, both the device under test and the peripheral device do not meet their respective expectations. For instance, if a device under test is commanded to turn on but fails to turn on, the response of the device under test does not meet the test action of turning on the device under test and the response of the peripheral device also fails to meet the test action of turning on the device under test as the peripheral device is now instead turned on when a test action of turning on the peripheral device has not been expected. If the peripheral device alone meets the expectation of not having been turned on and remains in the turned off state, a response of the device under test which does not meet the test action of turning on the device under test can be treated as a fault attributed to the device under test. Details regarding the test actions, components and devices responsible for specific faults shall be provided in the test action database 36 such that upon retrieval of such information pertaining to a specific test action, useful and specific fault information can be provided to service personnel for further corrective actions. An example of a system exhibiting a cross-wire is illustrated in FIGS. 2-3.

FIG. 2 is a diagram depicting a heating system 42 where the heating output is jointly or alternatively provided by any one or more heaters 44 of the heating system 42. Each heater 44 includes a heat exchanger 58, a burner 54 functionally coupled to it and an igniter 50 for starting the burner 54. Each heater 44 receives a cold water supply via an inlet and supplies heated water via an outlet. A valve/flow sensor/inlet temperature sensor package 56 is provided at the inlet of each heater and an outlet temperature sensor 52 disposed at the outlet of each heater 44 is configured for measuring the water temperature at the outlet of each heater 44. A controller 46 is provided to control each heater 44. All three controllers 46 one for each heater 44 have been substantially co-located. Due to the close proximity of the controllers 46 for heaters A, B and C for ease of service, it is also easy for a service personnel to inadvertently mix up at least some of the wires. A connection between the controller 46 of a component, e.g., valve, flow sensor, inlet temperature sensor, igniter 50, burner 54, outlet temperature sensor 52 represents a physical connection, e.g., by wire, between the controller 46 and the component it controls. It shall be noted that, in FIG. 2, the physical connections of the control wires have been properly made. For instance, if the valve of heater A has been commanded to be disposed in an open position while the burner 54 is also turned on, a water flow will occur through the heat exchanger 58. The temperature sensor 52 will sense an increase in the water temperature. Referring back to FIG. 1, the valve can be seen as the device under test and the test action conducted on the valve includes opening the valve for allowing a flow of water and the response of the test action conducted on the valve includes a temperature response of the flow of water due to the act of opening the valve.

FIG. 3 is a diagram depicting the heating system 42 of FIG. 2 with the exception that the heater controllers 46 of heaters A and B have been mis-wired. Here, wire 60 should have been used for connecting controller B and heater B. However, due to mis-wiring, controller B is instead connected to the valve of heater A. A mis-wiring has also been made between controller A and heater B. Here, wire 48 should have been used for connecting controller A and heater A. Again, due to mis-wiring, controller A is instead connected to the valve of heater B. A valve turn on command from A will cause the valve of heater B to open. Since the valve of heater A remains closed, the outlet temperature sensor 52 of heater A cannot sense an expected temperature or temperature change after a brief delay. The temperature response of the command for opening a valve as indicated at the outlet temperature sensor 52 therefore does not meet the expected result as retrieved from the test action database. The temperature response of the same command that is meant for heater A now causes a flow in heater B. A flow in heater B can cause its outlet temperature sensor to sense a drop or rise in temperature depending on the distribution of residual heat in the water disposed in heat exchanger 58 of heater B. The temperature response of the command for opening a valve in heater A as indicated at the outlet temperature sensor 52 of heater B therefore does not meet the expected result as retrieved from the test action database. As both responses do not meet the expected results, a cross-wire fault is said to have occurred. If the temperature response of the same command for opening a valve of heater A as indicated at the outlet temperature sensor 52 of heater B meets the expected result, e.g., with little to no change in temperature, heater B is treated as behaving according to the valve turn on command that is only meant for heater A. If the temperature response of the same command for opening a valve of heater A as indicated at the outlet temperature sensor 52 of heater A does not meet the expected result, a fault that points to the valve of heater A is raised such that the valve can be examined further. At a higher level, the present diagnostic method can be applied at the device level. In other words, the identification of a cross-wire fault can be used to pinpoint the devices that are potentially involved in a cross-wire fault. Using the same example shown in FIGS. 2-3, if the device under test is a heating device or heater and the test action conducted the device under test includes turning on the device under test, a cross-wire fault can cause a peripheral heating device to turn on instead. Without a present diagnostic method, a mis-wiring event can have severe and long-lasting consequences. For instance, if the mis-wiring event had allowed cross-wired heaters A and B to otherwise function to meet heating demands, true usages on the heaters may not have been reflected by their respective usage data and the maintenance or replacement of parts could be performed on the wrong heater and not on the heater requiring it. The diagnostic method can be executed using any one of the controllers 46 or any remote controller or computing device configured to have access to the properties of the tested device and peripheral devices, test action database and control inputs, e.g., of the controller 46 corresponding to the tested device.

The detailed description refers to the accompanying drawings that show, by way of illustration, specific aspects and embodiments in which the present disclosed embodiments may be practiced. These embodiments are described in sufficient detail to enable those skilled in the art to practice aspects of the present invention. Other embodiments may be utilized, and changes may be made without departing from the scope of the disclosed embodiments. The various embodiments can be combined with one or more other embodiments to form new embodiments. The detailed description is, therefore, not to be taken in a limiting sense, and the scope of the present invention is defined only by the appended claims, with the full scope of equivalents to which they may be entitled. It will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present disclosed embodiments includes any other applications in which embodiments of the above structures and fabrication methods are used. The scope of the embodiments should be determined with reference to the appended claims, along with the full scope of equivalents to which such claims are entitled.

What is claimed herein is:

1. A diagnostic method of a system having at least one device under test and at least one peripheral device, said diagnostic method comprising:
(a) obtaining a response of a test action conducted on the at least one device under test; and
(b) obtaining a response of a test action conducted on the at least one peripheral device;
wherein if said response of said test action conducted on the at least one device under test deviates from an expected result based on said test action conducted on the at least one device under test and said response of said test action conducted on the at least one peripheral device deviates from an expected result based on said test action conducted on the at least one peripheral device, a cross-wire fault is raised and if said response of said test action conducted on the at least one device under test deviates from an expected result based on said test action conducted on the at least one device under test and said response of said test action conducted on the at least one peripheral device does not deviate from an expected result based on said test action conducted on the at least one peripheral device, a device under test fault is raised.

2. The diagnostic method of claim 1, said at least one device under test is a valve and said test action conducted on the at least one device under test comprises opening the valve for allowing a flow of water and said response of said test action conducted on the at least one device under test comprises a temperature response of the flow of water due to said act of opening the valve.

3. The diagnostic method of claim 1, said at least one device under test is a heating device and said test action conducted on the at least one device under test comprises turning on said at least one device under test.

4. The diagnostic method of claim 1, further comprising running said test action as part of a normal operation of said at least one device under test.

5. The diagnostic method of claim 1, further comprising running said test action as part of an exerciser.

6. A diagnostic method of a system having at least one device under test and at least one peripheral device, said diagnostic method comprising:
(a) obtaining a response of a test action conducted on the at least one device under test; and
(b) obtaining a response of a test action conducted on the at least one peripheral device;
wherein if said response of said test action conducted on the at least one device under test deviates from an expected result based on said test action conducted on the at least one device under test and said response of said test action conducted on the at least one peripheral device deviates from an expected result based on said test action conducted on the at least one peripheral device, a cross-wire fault is raised and if said response of said test action conducted on the at least one device under test deviates from an expected result based on said test action conducted on the at least one device under test and said response of said test action conducted on the at least one peripheral device does not deviate from an expected result based on said test action conducted on the at least one peripheral device, a device under test fault is raised and said at least one device under test is a valve, said test action conducted on the at least one device under test comprises opening the valve for allowing a flow of water and said response of said test action conducted on the at least one device under test comprises a temperature response of the flow of water due to said act of opening the valve.

7. The diagnostic method of claim 6, said at least one device under test is a heating device and said test action conducted on the at least one device under test comprises turning on said at least one device under test.

8. The diagnostic method of claim 6, further comprising running said test action as part of a normal operation of said at least one device under test.

9. The diagnostic method of claim 6, further comprising running said test action as part of an exerciser.

10. A diagnostic method of a system having at least one device under test and at least one peripheral device, said diagnostic method comprising:
(a) obtaining a response of a test action conducted on the at least one device under test; and
(b) obtaining a response of a test action conducted on the at least one peripheral device;
wherein if said response of said test action conducted on the at least one device under test deviates from an expected result based on said test action conducted on the at least one device under test and said response of said test action conducted on the at least one peripheral device deviates from an expected result based on said test action conducted on the at least one peripheral device, a cross-wire fault is raised and if said response of said test action conducted on the at least one device under test deviates from an expected result based on said test action conducted on the at least one device under test and said response of said test action conducted on the at least one peripheral device does not deviate from an expected result based on said test action conducted on the at least one peripheral device, a device under test fault is raised and said at least one device under test is a heating device and said test action conducted on the at least one device under test comprises turning on said at least one device under test.

11. The diagnostic method of claim 10, said at least one device under test is a valve and said test action conducted on the at least one device under test comprises opening the valve for allowing a flow of water and said response of said test action conducted on the at least one device under test comprises a temperature response of the flow of water due to said act of opening the valve.

12. The diagnostic method of claim 10, further comprising running said test action as part of a normal operation of said at least one device under test.

13. The diagnostic method of claim 10, further comprising running said test action as part of an exerciser.
